(19) United States
(12) Patent Application Publication
(10) Pub. No.: US 2026/0196281 A1
(43) Pub. Date: Jul. 9, 2026

(54) STORAGE DEVICE THAT ANALYZES DETERIORATION CHARACTERISTICS OF MEMORY BLOCKS AND PERFORMS DETERIORATION BLOCK MANAGEMENT OPERATION

(71) Applicant: SAMSUNG ELECTRONICS CO., LTD., Suwon-si (KR)

(72) Inventors: Minoh KIM, Suwon-si (KR); Myungkyu KIM, Suwon-si (KR); Junyeong SEOK, Suwon-si (KR)

(73) Assignee: SAMSUNG ELECTRONICS CO., LTD., Suwon-si (KR)

(21) Appl. No.: 19/398,463

(22) Filed: Nov. 24, 2025

(30) Foreign Application Priority Data
Jan. 7, 2025 (KR) 10-2025-0002289

(51) Int. Cl. G11C 16/34; G11C 16/32

(52) U.S. Cl. CPC G11C 16/3495; G11C 16/32; G11C 16/3459

(57) ABSTRACT

A storage device includes: a memory device including a plurality of memory blocks; and a memory controller configured to manage, based on one or more deterioration characteristics, the plurality of memory blocks, wherein the memory controller is further configured to: receive, from the memory device, at least one of a number of off-cells of memory cells of the memory device in an erase state or a highest program state or a number of on-cells of the memory cells of the memory device in the erase state or the highest program state, analyze the one or more deterioration characteristics of the plurality of memory blocks based on the least one of the number of off-cells or the number of on-cells to obtain an analysis result, change one or more bias conditions based on the analysis result, and operate the memory device based on the changed one or more bias conditions.

### CROSS-REFERENCE TO RELATED APPLICATIONS

This application claims priority under 35 U.S.C. § 119 to Korean Patent Application No. 10-2025-0002289 filed on Jan. 7, 2025, in the Korean Intellectual Property Office, the disclosure of which is incorporated by reference herein in its entirety.

### BACKGROUND

The present disclosure relates to a semiconductor memory device, and more specifically, to a storage device that analyzes deterioration characteristics of memory blocks and performs deterioration block management operation.

Semiconductor memories may be classified as a volatile memory or a non-volatile memory, for example. Typically, the volatile memories (e.g., a dynamic random access memory (DRAM) or a static random access memory (SRAM)) may exhibit faster read and/or write speeds when compared to the non-volatile memory. However, data stored in the volatile memory may disappear when a power applied to the volatile memory is turned off. In contrast, the non-volatile memory may retain the data even when the power is turned off.

A representative example of the non-volatile memory may be a flash memory. The flash memory may store multi-bit data of two or more bits in one memory cell. The flash memory may have at least one erase state and a plurality of program (e.g., writing) states depending on threshold voltage distributions.

Flash memory has a read margin between each program state. However, the threshold voltage of flash memory may change due to various reasons. For example, the threshold voltage of flash memory may change due to coupling noise, pass voltage disturbance, program voltage disturbance, or read pass voltage disturbance. If the threshold voltages of memory cells change, deterioration may occur.

When performing a read operation, a select read voltage may be provided to a selected word line and a high-voltage read pass voltage may be provided to unselected word lines. If a high-voltage read pass voltage is repeatedly applied to unselected word lines, memory cells may be stressed. The threshold voltage of stressed memory cells may increase. As a result, a read failure may occur during a read operation.

### SUMMARY

Proved is a storage device that analyzes the deterioration characteristics of memory cells and performs a deterioration block management operation according to the analyzed deterioration characteristics.

According to an aspect of the disclosure, a storage device includes: a memory device including a plurality of memory blocks; and a memory controller configured to manage, based on one or more deterioration characteristics, the plurality of memory blocks, wherein the memory controller is further configured to: receive, from the memory device, at least one of a number of off-cells of memory cells of the memory device in an erase state or a highest program state or a number of on-cells of the memory cells of the memory device in the erase state or the highest program state, analyze the one or more deterioration characteristics of the plurality of memory blocks based on the least one of the number of off-cells or the number of on-cells to obtain an analysis result, change one or more bias conditions based on the analysis result, and operate the memory device based on the changed one or more bias conditions.

According to an aspect of the disclosure, a memory controller which controls a memory device, includes: a processor configured to: count, using a cell counter of the memory device, at least one a number of on-cells of memory cells of the memory device in an erase state or a highest program state or a number of off-cells of the memory cells in the erase state or the highest program state; analyze one or more deterioration characteristics of a memory block the at least one of the number of on-cells or the number of off-cells to obtain an analysis result; change one or more bias conditions of the memory device based on the analysis result; and control the memory device to operate based on the changed one or more bias conditions.

According to an aspect of the disclosure, a management method of a memory controller controlling a memory device, includes: counting at least one of a number of on-cells of memory cells of the memory device in an erase state or a highest program state or a number of off-cells of the memory cells of the memory device in the erase state or the highest program state; analyzing one or more deterioration characteristics of a memory block based on the at least one of the number of on-cells or the number of off-cells to obtain an analysis result; changing one or more bias conditions of the memory device according to the analysis result; and operating the memory device according to the changed one or more bias conditions.

### BRIEF DESCRIPTION OF THE DRAWINGS

The above and other aspects and features of the present disclosure will become apparent by describing in detail embodiments thereof with reference to the accompanying drawings, in which:

FIG. 1 is a block diagram illustrating an example embodiment of a storage device according to one or more embodiments of the present disclosure;

FIG. 2 is a block diagram illustrating an example embodiment of the memory device illustrated in FIG. 1 according to one or more embodiments of the present disclosure;

FIG. 3 is a circuit diagram illustrating an example embodiment of a memory block BLK1 of the memory cell array illustrated in FIG. 2 according to one or more embodiments of the present disclosure;

FIG. 4 is a circuit diagram illustrating cell strings selected by the first string selection line SSL1 from among the cell strings of the memory block BLK1 illustrated in FIG. 3 according to one or more embodiments of the present disclosure;

FIG. 5 is a diagram illustrating an example embodiment of threshold voltage distributions of memory cells illustrated in FIG. 4 according to one or more embodiments of the present disclosure;

FIG. 6 is a block diagram illustrating an example embodiment of the memory controller in FIG. 1 according to one or more embodiments of the present disclosure;

FIG. 7 is a diagram illustrating an example embodiment of a pre-defined table illustrated in FIG. 6 according to one or more embodiments of the present disclosure;

FIG. 8 is a graph illustrating an example embodiment of an incremental step pulse programming (ISPP) start program voltage illustrated in FIG. 7 according to one or more embodiments of the present disclosure;

FIG. 9 is a flowchart illustrating an example embodiment of the deterioration block management operation of the memory deterioration management unit illustrated in FIG. 6 according to one or more embodiments of the present disclosure;

FIG. 10 is a block diagram illustrating another embodiment of the memory deterioration management unit illustrated in FIG. 1 according to one or more embodiments of the present disclosure;

FIGS. 11 and 12 are graphs illustrating the deterioration characteristics and deterioration improvement of memory cells due to read disturbance according to one or more embodiments of the present disclosure;

FIGS. 13, 14, and 15 are graphs illustrating the deterioration characteristics and deterioration improvement of memory cells due to retention according to one or more embodiments of the present disclosure;

FIG. 16 is a flowchart illustrating an example embodiment of a deterioration block management operation of the memory deterioration management unit illustrated in FIG. 10 according to one or more embodiments of the present disclosure;

FIG. 17 is a graph illustrating the deterioration characteristics due to read disturbance according to the progress of the PE cycle according to one or more embodiments of the present disclosure;

FIG. 18 is a graph illustrating the deterioration characteristics due to retention according to the progress of the PE cycle according to one or more embodiments of the present disclosure;

FIG. 19 is a graph illustrating the deterioration characteristics of memory cells due to read disturbance and/or retention according to one or more embodiments of the present disclosure;

FIG. 20 is a diagram illustrating an example embodiment of a memory device having a multi-stack structure according to one or more embodiments of the present disclosure; and

FIG. 21 is a block diagram illustrating an example in which a storage device according to an embodiment of the present disclosure is implemented with a solid state drive (SSD) according to one or more embodiments of the present disclosure.

### DETAILED DESCRIPTION

Below, example embodiments of the present disclosure will be described in detail with reference to the drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

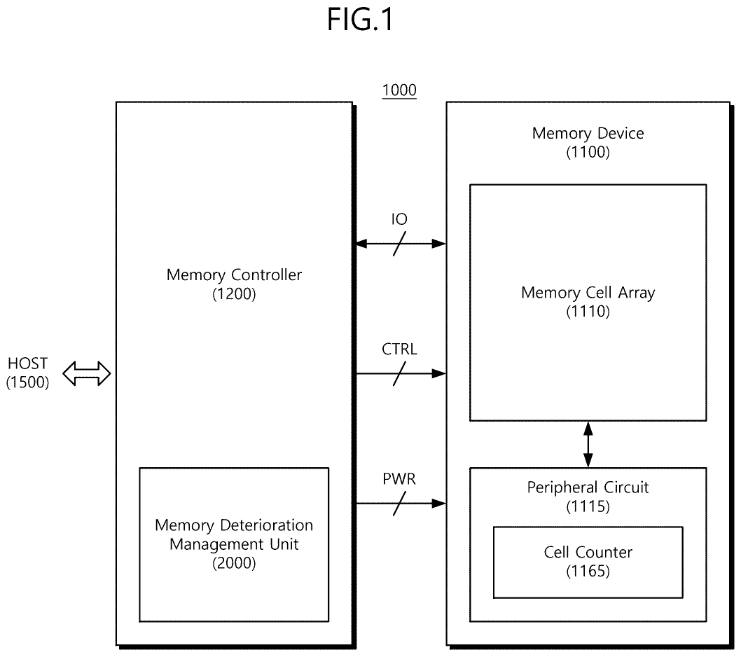

FIG. 1 is a block diagram illustrating an example embodiment of a storage device according to the present disclosure. Referring to FIG. 1, the storage device 1000 may include a memory device 1100 and a memory controller 1200. The storage device 1000 may be a flash storage device based on a flash memory. For example, the storage device 1000 may be implemented as a solid-state drive (SSD), a universal flash storage (UFS), a memory card, or the like. As understood by one of ordinary skill in the art, the storage device may be any suitable non-volatile memory device known to one of ordinary skill in the art.

The storage device 1000 may communicate with the host 1500 through a host interface. The storage device 1000 may receive a write request to store data in the memory device 1100 or a read request to read data stored in the memory device 1100 from the host 1500. The storage device 1000 may receive a logical address for identifying data from the host 1500.

The memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may have a vertical 3D structure. The memory cell array 1110 may include a plurality of memory cells. Multi-bit data may be stored in each memory cell.

The memory cell array 1110 may be located (e.g., disposed) next to or above the peripheral circuit 1115 in terms of the design layout structure. A structure in which the memory cell array 1110 is positioned over the peripheral circuit 1115 may be referred to as a cell on peripheral (COP) structure (e.g., memory cell array is placed above the control logic circuits (the peripheral circuit)). This structure reduces the overall chip size by stacking the memory cells on top of the control circuitry.

The memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure (e.g., two or more chips interconnected to form a larger, more complex system-on-chip (SoC)).

The peripheral circuit 1115 may include analog circuits and/or digital circuits required to store data in the memory cell array 1110 or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200.

The peripheral circuit 1115 may include a cell counter 1165. The cell counter 1165 may count the number of memory cells existing in a specific area of erase and program states. For example, the cell counter 1165 may count the number of off-cells in the erase state and/or the number of on-cells in the highest program state. The number of off-cells in the erase state and the number on-cells in the highest program state may be determined for a same time period. The cell counter 1165 may provide the number of off-cells and/or the number of on-cells to the memory controller 1200. In one or more examples, an off-cell may refer to a memory cell having a first voltage, and an on-cell may refer to a memory cell having a second voltage higher than the first voltage.

The memory controller 1200 may include a memory deterioration management unit 2000. The memory deterioration management unit 2000 may receive a cell count from the memory device 1100 and perform a deterioration block management operation. The memory controller 1200 may receive the number of on-cells in the erase state and/or off-cells in the highest program state of the memory block, and may analyze the deterioration characteristics of the memory block using the cell count. The memory controller 1200 may change bias conditions according to the result of the deterioration characteristic analysis of the memory block, and may control the operation of the memory device 1100 according to the changed bias conditions.

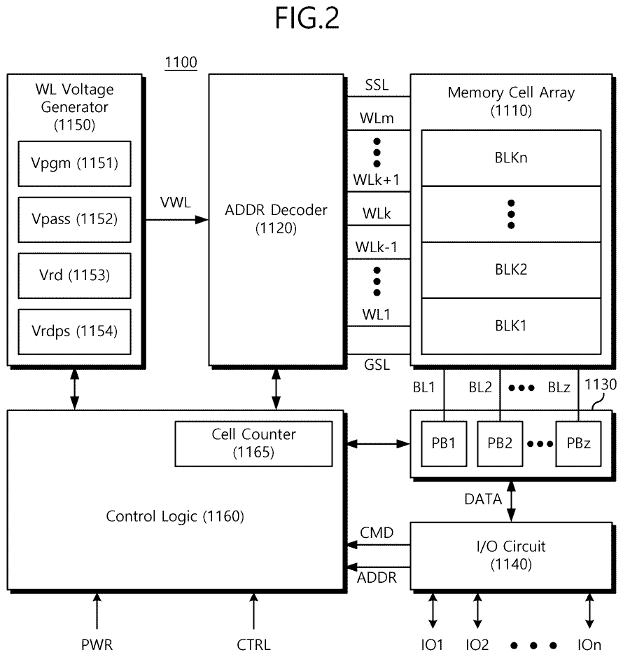

FIG. 2 is a block diagram illustrating an example embodiment of the memory device illustrated in FIG. 1. Referring to FIG. 2, the memory device 1100 may include the memory cell array 1110 and the peripheral circuit 1115 (see FIG. 1). The peripheral circuit 1115 may include an address decoder 1120, a page buffer circuit 1130, a data input/output circuit 1140, a word line voltage generator 1150, and a control logic 1160.

The memory cell array 1110 may include a plurality of memory blocks BLK1 to BLKn. Each memory block may include a plurality of pages. Each page may include a plurality of memory cells. Each memory cell may store multi-bit data (e.g., two or more bits). Each memory block may correspond to an erase unit, and each page may correspond to a read unit and/or a write unit. Each memory block may be the same size or different size.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selected word line sWL and the remaining word lines (WL1 to WLk−1, WLk+1 to WLm) are unselected word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selected word line.

The page buffer circuit 1130 may be connected to the memory cell array 1110 through bit lines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller 1200 (refer to FIG. 1) through the input/output lines IO1 to IOn. The input/output circuit 1140 may receive program data from the memory controller 1200 during a program operation. In one or more examples, the input/output circuit 1140 may provide data read from the memory cell array 1110 to the memory controller 1200 during a read operation.

The word line voltage generator 1150 may receive internal power from the control logic 1160 and generate a word line voltage VWL required to read or write data. The word line voltage VWL may be provided to a selected word line sWL or unselected word lines uWL through the address decoder 1120.

The word line voltage generator 1150 may include a program voltage generator 1151 and a pass voltage generator 1152. The program voltage generator 1151 may generate a program voltage Vpgm provided to the selected word line sWL during a program operation. The pass voltage generator 1152 may generate a pass voltage Vpass provided to the selected word line sWL and the unselected word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselected word lines uWL. The read pass voltage Vrdps may be sufficient voltage to turn on memory cells connected to the unselected word lines uWL during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

The control logic 1160 may include a cell counter 1165. The cell counter 1165 may count the number of memory cells existing in a specific area of erase and program states of one or more memory blocks. The cell counter 1165 may calculate the number of on-cells or off-cells in an erase state during a deterioration block management operation. The cell counter 1165 may calculate the number of on-cells or off-cells in a plurality of program states. The cell counter 1165 may provide the number of off-cells and/or the number of on-cells to the memory controller 1200 at the request of the memory deterioration management unit 2000. The cell counter 1165 may be implemented by one or more instructions executed by the control logic 1160. In one or more examples, the cell counter 1165 may be implemented by one or more logic circuits of the control logic 1160.

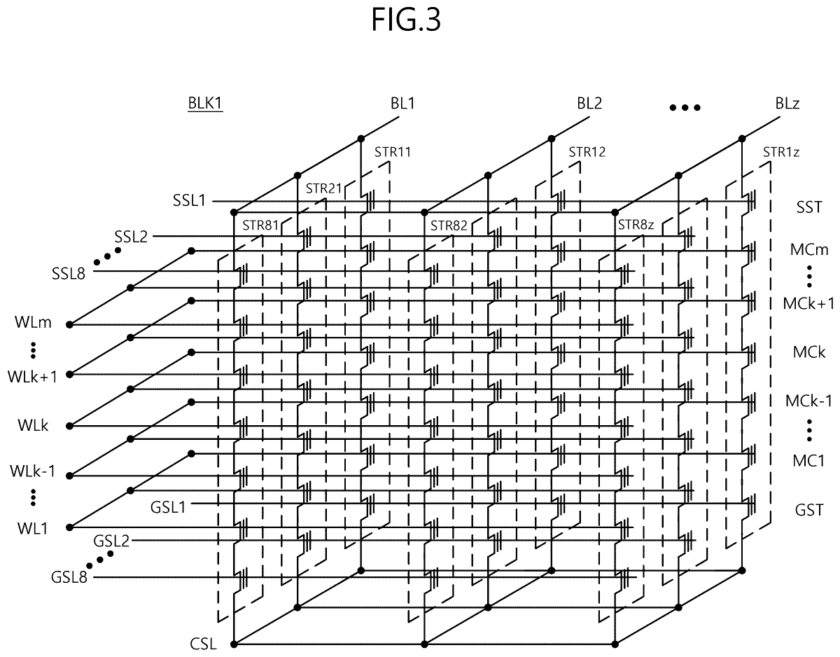

FIG. 3 is a circuit diagram illustrating an example embodiment of a memory block BLK1 of the memory cell array illustrated in FIG. 2.

Referring to FIG. 3, in the memory block BLK1, a plurality of cell strings STR11 to STR8z may be formed between the bit lines BL1 to BLz and a common source line CSL. Each cell string includes a string selection transistor SST, a plurality of memory cells MC1 to MCm, and a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLZ, and the ground selection transistors GST may be connected with the common source line CSL.

The first to m-th word lines WL1 to WLm may be connected with the plurality of memory cells MC1 to MCm in a row direction. The first to z-th bit lines BL1 to BLz may be connected with the plurality of memory cells MC1 to MCm in a column direction. First to z-th page buffers PB1 to PBz may be connected with the first to z-th bit lines BL1 to BLz.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m−1)-th memory cells MC2 to MCm−1 that are placed at the same heights from the substrate may be respectively connected with the second to (m−1)-th word lines WL2 to WLm−1, respectively.

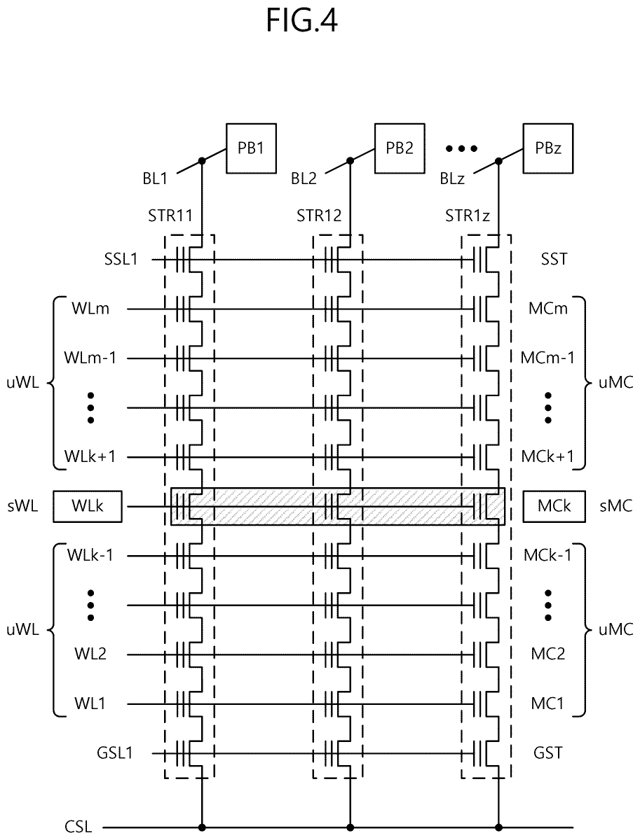

FIG. 4 is a circuit diagram illustrating cell strings selected by the first string selection line SSL1 from among the cell strings of the memory block BLK1 illustrated in FIG. 3.

The cell strings STR11 to STR1z may be selected by the first string selection line SSL1. The cell strings STR11 to STR1z may be connected to the first to z-th bit lines BL1 to BLz, respectively. The first to z-th page buffers PB1 to PBz may be connected to the first to z-th bit lines BL1 to BLz, respectively.

The cell string STR11 may be connected to the first bit line BL1 and the common source line CSL. The cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The cell string STR12 may be connected to the second bit line BL2 and the common source line CSL. The cell string STR1z may be connected to the z-th bit line BLz and the common source line CSL.

The first word line WL1 and the m-th word line WLm may be edge word lines (edge WL). The second word line WL2 and the (m−1)-th word line WLm−1 may be edge adjacent word lines. The k-th word line WLk may be a selected word line sWL. The (k−1)-th word line WLk−1 and the (k+1)-th word line WLk+1 may be adjacent word lines adjacent to the selected word line. If the k-th word line WLk is the selected word line sWL, the remaining word lines WL1 to WLk−1 and WLk+1 to WLm may be unselected word lines uWL.

The first memory cells MC1 and the m-th memory cells MCm may be edge memory cells. The second memory cells MC2 and the (m−1)-th memory cells MCm−1 may be edge adjacent memory cells. The k-th memory cells MCk may be selected memory cells sMC. The (k−1)-th memory cells MCk−1 and the (k+1)-th memory cells MCk+1 may be memory cells adjacent to the selected memory cells (adjacent MC). If the k-th memory cells MCk are selected memory cells sMC, the remaining memory cells MC1 to MCk−1 and MCk+1 to MCm may be unselected memory cells uMC.

A set of memory cells selected by one string selection line and connected to one word line may be one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selected page, and pages connected to the second to eighth string selection lines SSL2 to SSL8 are unselected pages.

The first word line WL1 is a first edge word line (Edge1 WL), and the second word line WL2 is a first edge adjacent word line (Edge1 adjacent WL). The m-th word line WLm is the second edge word line (Edge2 WL), and the (m−1)-th word line WLm−1 is the second edge adjacent word line (Edge2 adjacent WL). And word lines between the first and second edge adjacent word lines are middle word lines. For example, the k-th word line WLk (k=3 to m−2) between the second word line WL2 and the (m−1)-th word line WLm−1 is a middle word line.

In the read operation, if the second word line WL2 is the selected word line sWL, the remaining word lines may be unselected word lines uWL. The second word line WL2 may be a first edge adjacent word line (Edge1 adjacent WL). The second memory cells MC2 may be selected memory cells sMC. The remaining memory cells may be unselected memory cells uMC.

If the (m−1)-th word line WLm−1 is the selected word line sWL, the remaining word lines may be unselected word lines uWL. The (m−1)-th word line WLm−1 may be a second edge adjacent word line. The (m−1)-th memory cells MCm−1 may be selected memory cells sMC. The remaining memory cells may be unselected memory cells uMC.

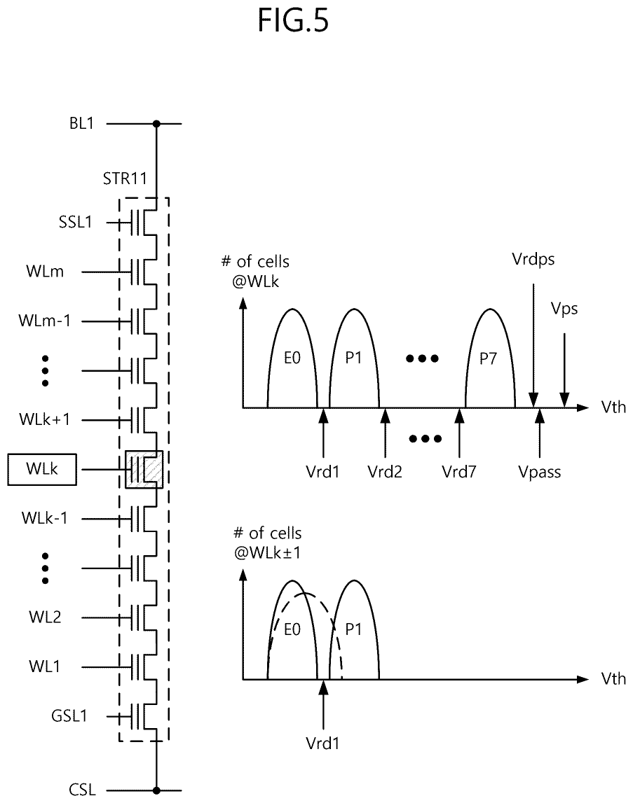

FIG. 5 is a diagram illustrating an example embodiment of threshold voltage distributions of memory cells illustrated in FIG. 4.

An abscissa denotes a threshold voltage Vth of memory cells, and an ordinate denotes the number of memory cells. 3-bit data may be stored in one memory cell. A 3-bit memory cell may have one of eight states (E0, P1 to P7) according to the threshold voltage distribution. E0 represents an erase state, and P1 to P7 represent program states.

During a read operation, the selection read voltages Vrd1 to Vrd7 may be provided to the selected word line sWL, and the pass voltage Vps and/or the read pass voltage Vrdps may be provided to the unselected word lines uWL. The pass voltage Vps and/or the read pass voltage Vrdps may be a voltage sufficient to turn on the memory cells. For example, the pass voltage Vps may be provided to the adjacent word lines WLk+1, and the read pass voltage Vrdps may be provided to the unselected word lines other than the adjacent word lines.

The first selection read voltage Vrd1 may be a voltage level between the erase state E0 and the first program state P1. The second selection read voltage Vrd2 may be a voltage level between the first and second program states P1 and P2. In this way, the seventh selection read voltage Vrd7 may be a voltage level between the sixth and seventh program states P6 and P7.

When the first selection read voltage Vrd1 is applied, the memory cell in the erase state E0 may be an on-cell and the memory cell in the first to seventh program states P1 to P7 may be an off-cell. When the second selection read voltage Vrd2 is applied, the memory cell in the erase state E0 and the first program state P1 may be an on-cell, and the memory cell in the second to seventh program states P2 to P7 may be an off-cell. In this way, when the seventh selection read voltage Vrd7 is applied, the memory cell in the erase state E0 and the first to sixth program states P1 to P6 may be an on-cell and the memory cell in the seventh program state P7 may be an off-cell.

During a read operation, the k-th word line WLk may be selected. A power supply voltage may be applied to the string selection line SSL1 and the ground selection line GSL1, and the string select transistor SST and the ground select transistor GST may be turned on. In one or more examples, the selection read voltage Vrd may be provided to the selected word line sWL, and the read pass voltage Vrdps and/or the pass voltage Vps may be provided to the unselected word lines uWL.

When the read operation of the k-th word line WLk is repeatedly performed, the high voltage read pass voltage Vrdps may be repeatedly provided to the remaining word lines. At this time, a read disturbance may occur in the remaining word lines, and thus, the threshold voltage may be distorted. Memory cells connected to the k-th word line WLk may be off-cells when a selection read voltage is provided. For example, when the threshold voltage of the k-th memory cell is higher than the selection read voltage, the k-th memory cell may be an off-cell. When the k-th memory cell is an off-cell, a channel may be separated at the k-th memory cell. For example, a lower channel of the k-th memory cell may receive a ground voltage from the common source line CSL, and an upper channel of the k-th memory cell may have a negative channel voltage.

A channel voltage difference may occur between a lower channel and an upper channel with the k-th memory cell interposed the lower channel and the upper channel. Due to the channel voltage difference, hot carrier injection (HCI) may occur in an adjacent memory cells MCk+1 and/or MCk−1. For this reason, threshold voltages of memory cells connected to adjacent word lines WLk+1 and/or WLk−1 may be distorted. For example, the threshold voltages of memory cells in the erase state E0 may rise to enter the programmed state.

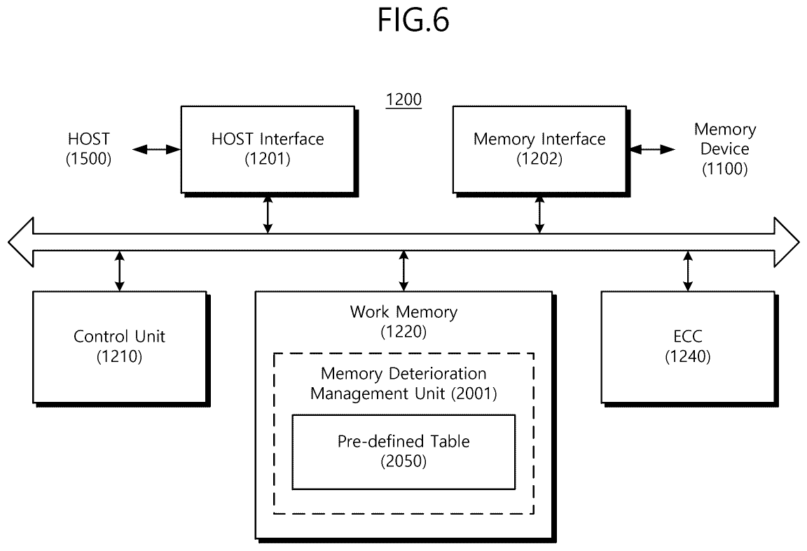

FIG. 6 is a block diagram illustrating an example embodiment of the memory controller in FIG. 1. Referring to FIG. 6, the memory controller 1200 may include a host interface 1201, a memory interface 1202, a control unit 1210, a work memory 1220, and an ECC circuit 1240. The work memory 1220 may drive a memory deterioration management unit 2001.

The memory controller 1200 may further include various components. For example, the memory controller 1200 may include a buffer memory that temporarily stores data resulting from a read or write operation of the flash memory 1100. The memory controller 1200 may further include a buffer control module for controlling the buffer memory, or a command generation module for generating a command for controlling a memory operation according to a request from the host 1500, etc.

The host interface 1201 may provide an interface between the host 1500 and the memory controller 1200. Standard interfaces may include various interface methods such as advanced technology attachment (ATA), serial ATA (SATA), external SATA (e-SATA), small computer small interface (SCSI), serial attached SCSI (SAS), peripheral component interconnection (PCI), PCI express (PCI-E), IEEE 1394, universal serial bus (USB), secure digital card (SD), multi-media card (MMC), embedded multi-media card (eMMC), universal flash storage (UFS), compact flash (CF), etc.

The memory interface 1202 may provide an interface between the flash memory 1100 and the memory controller 1200. For example, write or read data may be transmitted to and received from the flash memory 1100 through the memory interface 1202. The memory interface 1202 may provide commands and addresses to the flash memory 1100. The memory interface 1202 may provide data read from the flash memory 1100 to the memory controller 1200.

The control unit 1210 may include a central processing unit or microprocessor, and may control the overall operation of the memory controller 1200. The control unit 1210 may drive firmware loaded in the work memory 1220 to control the memory controller 1200.

The work memory 1220 may be implemented with various types of memory, such as DRAM, SRAM, or PRAM. The work memory 1220 may drive the memory deterioration management unit 2001 under the control of the control unit 1210. The memory deterioration management unit 2001 may receive deterioration management data stored in the memory device 1100 at power-up.

The memory deterioration management unit 2001 may receive deterioration management data and generate a pre-defined table 2050. The pre-defined table 2050 may be generated using the deterioration management data. The memory deterioration management unit 2001 may perform a deterioration block management operation using the pre-defined table 2050.

The ECC circuit 1240 may generate an error correction code (ECC) to correct fail bits or error bits of data received from the flash memory 1100. The ECC circuit 1240 may perform error correction encoding on data provided to the flash memory 1100 to form data to which a parity bit is added. Parity bits may be stored in flash memory 1100.

The ECC circuit 1240 may perform error correction decoding on data output from the flash memory 1100. The ECC circuit 1240 may correct errors using parity. The ECC circuit 1240 may correct errors using coded modulation, such as low density parity check (LDPC) code, BCH code, turbo code, Reed-Solomon code, convolution code, recursive systematic code (RSC), trellis-coded modulation (TCM), and block coded modulation (BCM).

The ECC circuit 1240 may have an error correction allowable range. For example, the ECC circuit 1240 may correct errors of up to 40 bits for 2K bytes of page data. In this case, the maximum allowable range in which the ECC circuit 1240 may correct errors is 40 bits. For example, the ECC circuit 1240 may not correct errors in the page if errors in more than 40 bits occur. A page whose errors may not be corrected like this is called a defected page. A memory cell in which an error occurs in a defective page is called a defected cell.

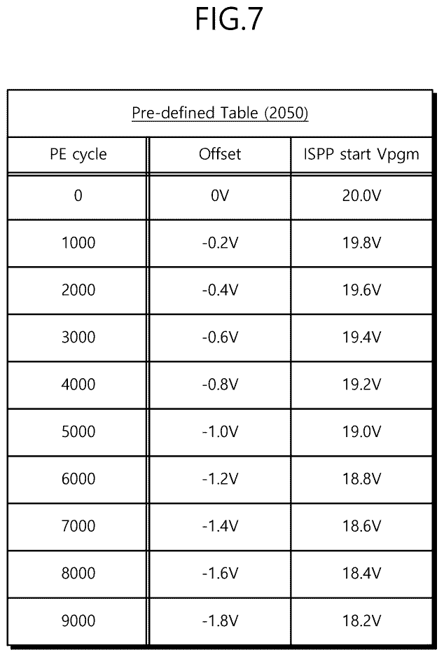

FIG. 7 is a diagram illustrating an example embodiment of a pre-defined table illustrated in FIG. 6. Referring to FIG. 7, the pre-defined table 2050 may include information about a program/erase (PE) cycle, an offset, and an ISPP start program voltage.

The offset and the ISPP start program voltage may change depending on the PE cycle. For example, the offset may decrease by 0.2 V every time the PE cycle is performed 1,000 times. When the PE cycle is 1,000, the ISPP start program voltage may decrease from 20.0 V to 19.8 V. When the PE cycle is 2,000, the offset may be −0.4 V and the ISPP start program voltage may be 19.6 V. When the PE cycle is 9,000, the offset may be −1.8 V and the ISPP start program voltage may be 18.2 V. As understood by one of ordinary skill in the art, the values in FIG. 7 are merely examples, and may be adjusted as required.

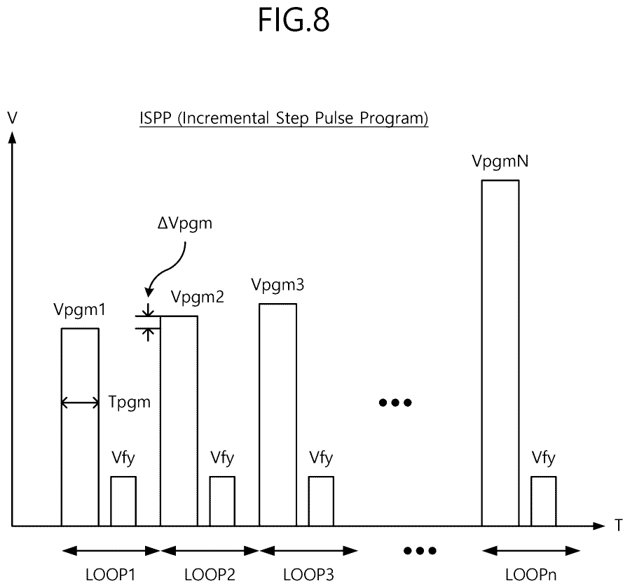

FIG. 8 is a graph illustrating an example embodiment of the ISPP start program voltage illustrated in FIG. 7. Referring to FIG. 8, the memory device 1100 may repeat program loops according to an ISSP (Incremental Step Pulse Program) method during a program operation. Each program loop may be provided with a program voltage Vpgm and a program verify voltage Vfy. The program voltage Vpgm may increase by ΔVpgm as the program loop progresses. The program voltage Vpgm may be provided for a program voltage application time Tpgm.

In the first program loop LOOP1, a program operation may be performed by a first program voltage Vpgm1 and the program verify voltage Vfy. The first program voltage Vpgm1 may be an ISPP start program voltage. In the second program loop LOOP2, a program operation may be performed by a second program voltage Vpgm2 and the program verify voltage Vfy. The second program voltage Vpgm2 may be higher than the first program voltage Vpgm1 by ΔVpgm.

In the third program loop LOOP3, a program operation may be performed by a third program voltage Vpgm3 and the program verify voltage Vfy. In the n-th program loop LOOPn, a program operation may be performed by the n-th program voltage VpgmN and the program verify voltage Vfy.

As the program loop increases, the program voltage Vpgm may increase by ΔVpgm. Memory cells that are program-passed in a program loop may be program-inhibited in the next program loop. Information on memory cells that have passed or failed by the program verify operation may be stored in the page buffer circuit (see FIG. 2, 1130). In one or more examples, a program loop may refer to a set of instructions executed a predetermined number of times.

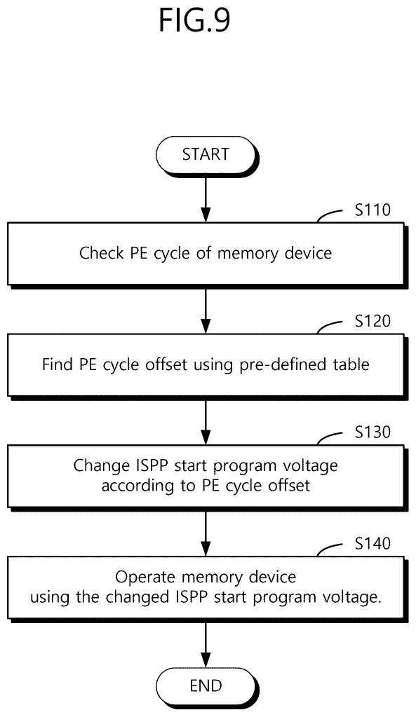

FIG. 9 is a flowchart illustrating an example embodiment of the deterioration block management operation of the memory deterioration management unit illustrated in FIG. 6. The memory deterioration management unit 2001 may perform the deterioration block management operation according to a pre-defined table 2050.

In operation S110, the memory deterioration management unit 2001 may check the PE cycle of the memory device 1100. The memory deterioration management unit 2001 may manage the PE cycle in units of 1,000, as illustrated in FIG. 7.

In operation S120, the memory deterioration management unit 2001 may find the PE cycle offset using the pre-defined table 2050. The PE cycle offset may be an ISPP start program voltage that changes according to the PE cycle. For example, the PE cycle offset may be reduced by 0.2 V each time the PE cycle changes in units of 1,000.

In operation S130, the memory deterioration management unit 2001 may change the ISPP program start voltage according to the PE cycle offset. For example, the memory deterioration management unit 2001 may set the ISPP program start voltage to 20.0 V until the PE cycle is performed 1,000 times. When the PE cycle reaches 1,000, the memory deterioration management unit 2001 may lower the ISPP start voltage to 19.8V. The memory deterioration management unit 2001 may lower it to 19.6V when the PE cycle reaches 2,000 times. The memory deterioration management unit 2001 may change the ISPP program start voltage according to the offset.

In operation S140, the memory deterioration management unit 2001 may operate the memory device 1100 using the changed ISPP program start voltage. The memory deterioration management unit 2001 may change the ISPP program start voltage according to the PE cycle and perform a program operation using the changed ISPP program start voltage. The memory deterioration management unit 2001 illustrated in FIG. 6 may perform a deterioration block management operation by changing the ISPP program start voltage according to the PE cycle using the pre-defined table 2050.

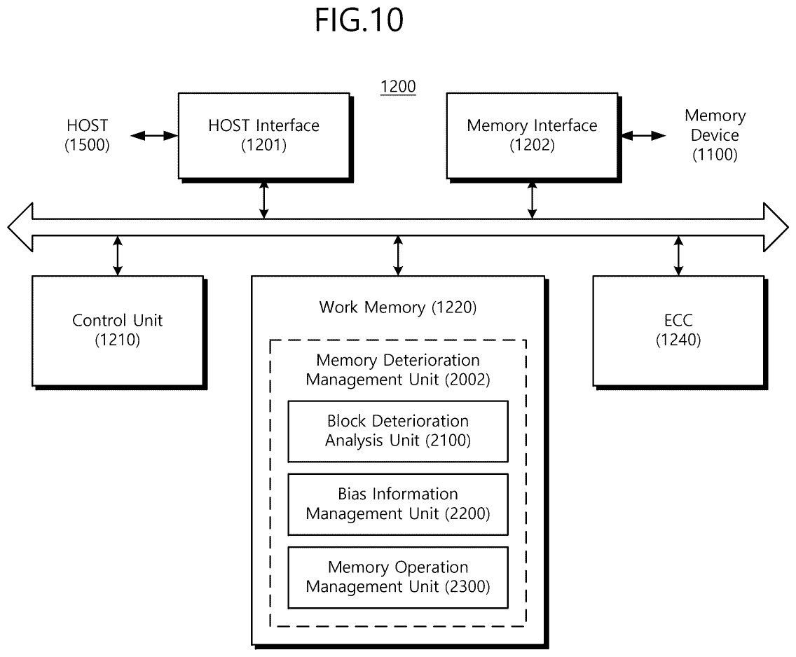

FIG. 10 is a block diagram illustrating one or more embodiments of the memory deterioration management unit illustrated in FIG. 1. Referring to FIG. 10, the memory controller 1200 may include a host interface 1201, a memory interface 1202, a control unit 1210, a work memory 1220, and an ECC circuit 1240.

The work memory 1220 may drive a memory deterioration management unit 2002. The work memory 1220 may drive the memory deterioration management unit 2002 under the control of the control unit 1210. The memory deterioration management unit 2002 may receive deterioration management data stored in the memory device 1100 at power-up. The memory deterioration management unit 2002 may include a block deterioration analysis unit 2100, a bias information management unit 2200, and a memory operation management unit 2300.

The block deterioration analysis unit 2100 may control the cell counter (1165, see FIG. 2) in the memory device 1100. The block deterioration analysis unit 2100 may find out the number of on-cells or off-cells of memory cells in the erase state and the highest program state by using the cell counter 1165. For example, the block deterioration analysis unit 2100 may find out the number of off-cells in the erase state and the number of on-cells in the highest program state.

The block deterioration analysis unit 2100 may analyze the deterioration characteristics of the corresponding memory blocks by using the number of on-cells and/or off-cells. The block deterioration analysis unit 2100 may analyze the deterioration characteristics due to read disturbance by using the number of off-cells in the erase state. The block deterioration analysis unit 2100 may analyze the deterioration characteristics due to retention by using the number of on-cells in the highest program state.

In vertical flash memory, deterioration due to retention may occur as charges move during the data retention period. The voltage distribution of the memory cell changes due to the movement of charges, which may affect the reliability of the data. Retention may mainly occur due to charge leakage, trap charge, temperature change, etc.

Retention due to charge leakage may occur when the voltage decreases due to the leakage of charges stored in the memory cell over time. Retention due to trap charge may occur when charges are trapped in the insulating layer of the memory cell, affecting the voltage distribution. Retention due to temperature change may occur when the temperature changes and the charge movement speed changes, resulting in voltage change.

The bias information management unit 2200 may change the bias conditions of the memory device 1100 based on the deterioration information analyzed by the block deterioration analysis unit 2100. For example, the bias information management unit 2200 may change program bias conditions such as a start voltage level, a verify voltage level, a program voltage increase range, a program voltage application time, or the number of program loops.

The memory operation management unit 2300 may operate the memory device 1100 with the changed bias conditions. For example, the memory operation management unit 2300 may operate the memory device 1100 using the changed program verify voltage and/or the changed number of program loops based on the changed bias conditions.

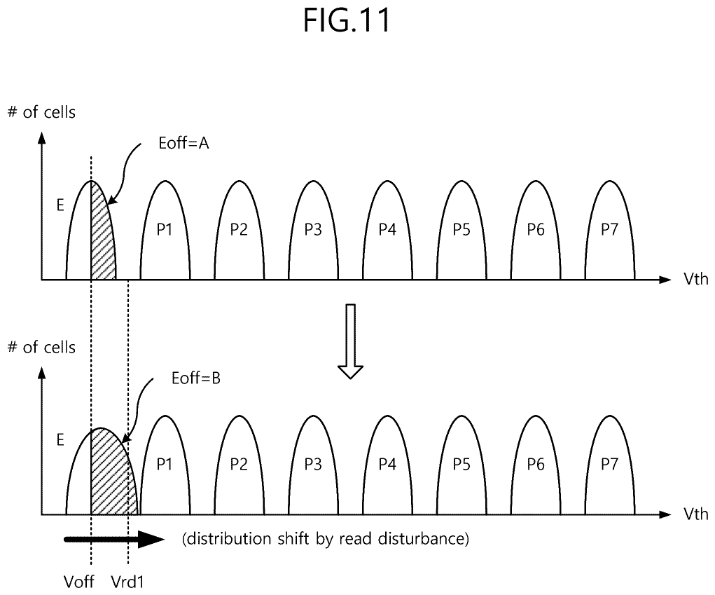

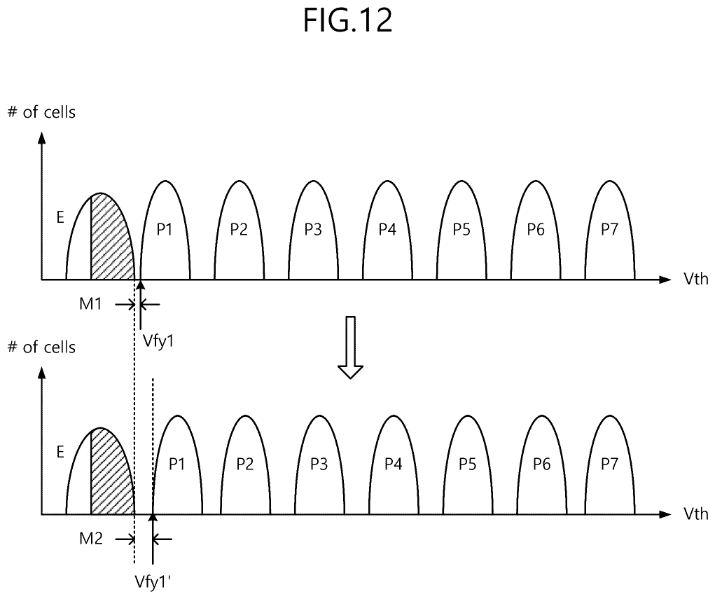

FIGS. 11 and 12 are graphs illustrating the deterioration characteristics and deterioration improvement of memory cells due to read disturbance. The memory cells may have an erase state E and the first to seventh program states P1 to P7. The seventh program state P7 may be the highest program state. The number of off-cells in the erase state may increase due to deterioration of the memory cells due to read disturbance.

Referring to FIG. 11, the block deterioration analysis unit 2100 may check the number of off-cells Eoff in the erase state E using the cell counter (1165, see FIG. 2) of the memory device 1100. The cell counter 1165 may count the number of off-cells based on the off-cell voltage Voff. Before the memory cells are deteriorated, the number of off-cells Eoff in the erase state E may be ‘A’.

The threshold voltage distribution of the memory cells may move in the right direction of the black arrow due to the read disturbance. After the memory cells are deteriorated, the number of off-cells Eoff in the erase state may be ‘B’. Due to the deterioration of the memory cells, the number of off-cells in the erase state may increase. When performing a read operation based on the first selection read voltage Vrd1, read errors may occur. For example, on-cells may be incorrectly read as off-cells based on the first selection read voltage Vrd1.

Referring to FIG. 12, when the threshold voltage distribution of memory cells in the erase state E moves toward the first program state P1, the read margin between the erase state E and the first program state P1 may decrease. For example, the read margin between the erase state E and the first program state P1 may be ‘M1’. As the read margin decreases, the probability of read errors may increase.

The bias information management unit 2200 may change the bias conditions to reduce the read errors due to the read disturbance. The bias information management unit 2200 may increase the program verify voltage. For example, the bias information management unit 2200 may increase the first program verify voltage from Vfy1 to Vfy1′. When the program verify voltage is increased, the read margin between the erase state E and the first program state P1 may be increased to ‘M2’.

When the memory operation management unit 2300 performs the program verify operation with the changed bias conditions, the read margin may be improved during the read operation. The memory deterioration management unit 2002 may reduce the deterioration due to read disturbance and increase the performance and reliability of the memory device 1100.

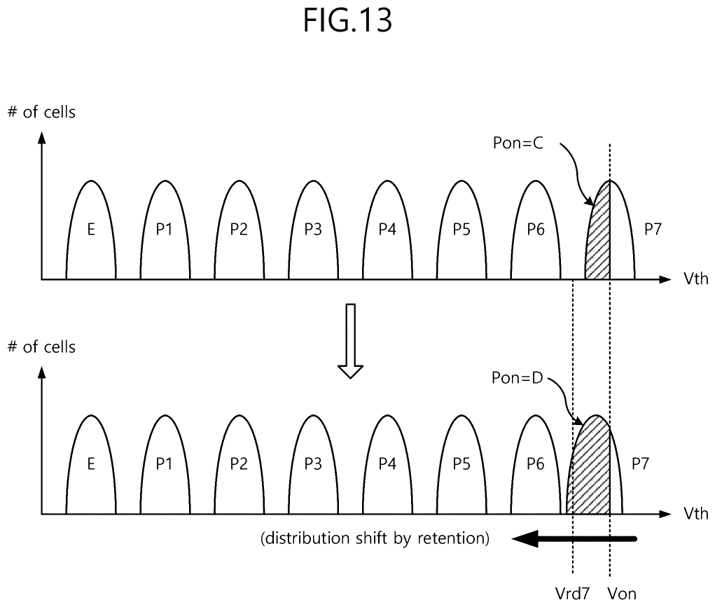

FIGS. 13 to 15 are graphs illustrating the deterioration characteristics and deterioration improvement of memory cells due to retention. Memory cells may have an erase state E and first to seventh program states P1 to P7. The seventh program state P7 may be the highest program state. The number of on-cells in the seventh program state may increase due to deterioration of memory cells due to retention.

Referring to FIG. 13, the block deterioration analysis unit 2100 may check the number of on-cells Pon in the seventh program state P7 using the cell counter (1165, see FIG. 2) of the memory device 1100. The cell counter 1165 may count the number of on-cells based on the on-cell voltage Von. Before the memory cells are deteriorated, the number of on-cells Pon in the seventh program state P7 may be ‘C’.

The threshold voltage distribution of the memory cells may move in the left direction of the black arrow due to retention. After the memory cells are deteriorated, the number of on-cells Pon in the seventh program state P7 may be ‘D’. Due to the deterioration of memory cells, the number of on-cells in the seventh program state may increase. When performing a read operation based on the seventh selection read voltage Vrd7, read errors may occur. For example, off-cells may be incorrectly read as on-cells based on the seventh selection read voltage Vrd7.

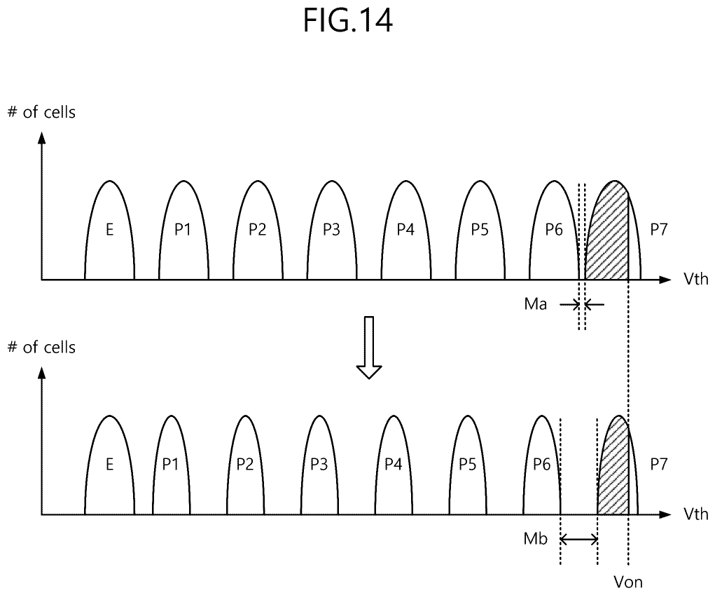

Referring to FIG. 14, when the threshold voltage distribution of memory cells in the seventh program state P7 moves toward the sixth program state P6, the read margin between the sixth program state P6 and the seventh program state P7 may decrease. For example, the read margin between the sixth and seventh program states P6 and P7 may be ‘Ma’. As the read margin decreases, the probability of read errors may increase.

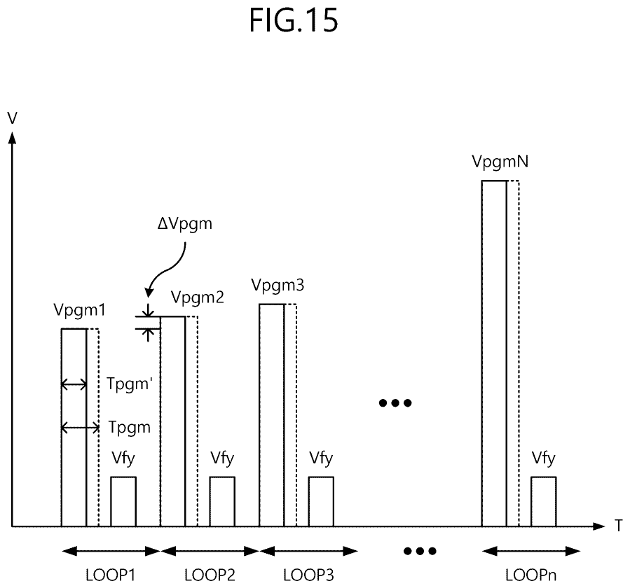

The bias information management unit 2200 may change the bias conditions to reduce deterioration due to retention. For example, the bias information management unit 2200 may reduce the ISPP program voltage application time. As shown in FIG. 15, when the ISPP program voltage application time is reduced from Tpgm to Tpgm′. As shown in FIG. 14, the width of each distribution may be reduced. When the width of each distribution is reduced, the read margin between the sixth and seventh program states P6 and P7 may be increased to ‘Mb’.

When the memory operation management unit 2300 performs a program operation with the changed bias conditions, the read margin may be improved during the read operation. The memory deterioration management unit 2002 may reduce deterioration due to retention and increase the performance and reliability of the memory device 1100.

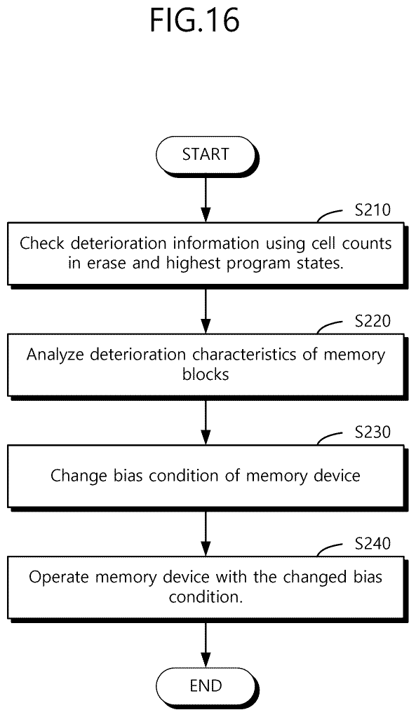

FIG. 16 is a flowchart illustrating an example embodiment of a deterioration block management operation of the memory deterioration management unit illustrated in FIG. 10. The memory deterioration management unit 2002 may perform the deterioration block management operation using the block deterioration analysis unit 2100, the bias information management unit 2200, and the memory operation management unit 2300.

In operation S210, the block deterioration analysis unit 2100 may check deterioration information using the number of memory cells in the erase state and the highest program state. The block deterioration analysis unit 2100 may check the number of memory cells in the erase state using the cell counter 1165 of the memory device 1100. For example, the block deterioration analysis unit 2100 may use the number of off-cells in the erase state.

In addition, the block deterioration analysis unit 2100 may check the number of memory cells in the highest program state using the cell counter 1165 of the memory device 1100. For example, the block deterioration analysis unit 2100 may use the number of on-cells in the highest program state.

In operation S220, the block deterioration analysis unit 2100 may analyze the deterioration characteristics of the memory blocks. The block deterioration analysis unit 2100 may analyze the deterioration state and degree of deterioration due to read disturbance of the corresponding memory block by using the number of off-cells in the erase state. In addition, the block deterioration analysis unit 2100 may analyze the deterioration state and the degree of deterioration due to retention of the corresponding memory block by using the number of on-cells in the highest program state.

In operation S230, the bias information management unit 2200 may change the bias conditions of the memory device 1100. The bias information management unit 2200 may change the bias conditions of the program operation and/or the read operation of the memory device 1100 based on the deterioration characteristics and the degree of deterioration of the block deterioration analysis unit 2100. For example, the bias information management unit 2200 may change the bias conditions of the program operation, such as the start voltage level, the verify voltage level, the step voltage or the step voltage application time, or the number of program loops.

In operation S240, the memory operation management unit 2300 may operate the memory device 1100 with the changed bias conditions. For example, the memory operation management unit 2300 may operate the memory device 1100 using the changed program verify voltage or the changed number of program loops based on the changed bias conditions.

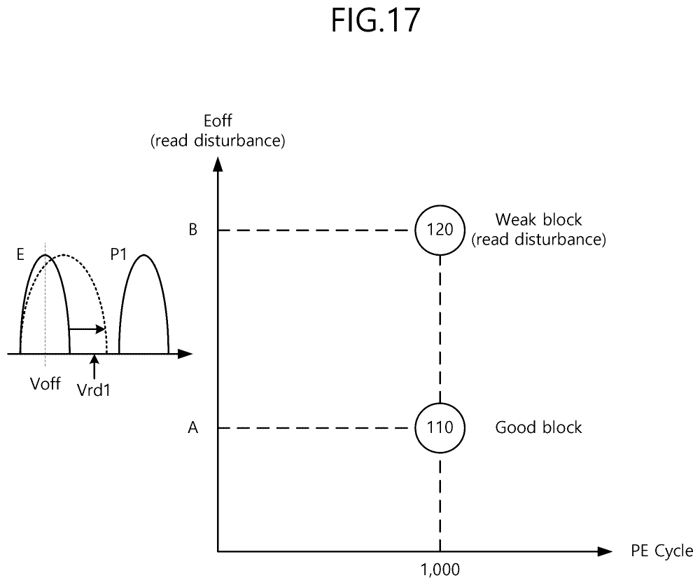

FIG. 17 is a graph illustrating the deterioration characteristics due to read disturbance according to the progress of the PE cycle. Memory cells may deteriorate due to read disturbance as the PE cycle progresses.

Referring to FIG. 17, when the PE cycle progresses (for example, 1,000 times), the memory blocks may be divided into good blocks 110 and weak blocks 120. The good block 110 may be a block that is relatively less affected by the read disturbance. The number of off-cells may be ‘A’ based on the off-cell voltage Voff. The weak block 120 may be a block that is relatively greatly affected by read disturbance. The number of off-cells may be ‘B’ based on the off-cell voltage Voff.

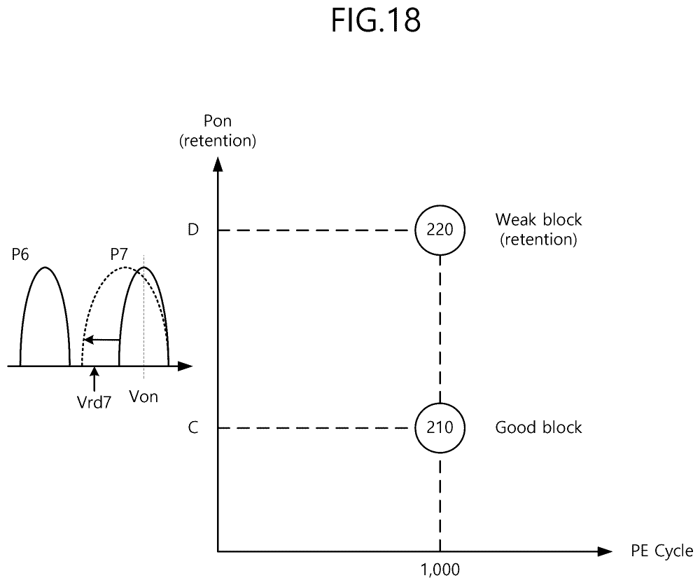

FIG. 18 is a graph illustrating the deterioration characteristics due to retention according to the progress of the PE cycle. Memory cells may deteriorate due to retention as the PE cycle progresses. The good block 210 may be a block that is relatively less affected by retention. The number of on-cells may be ‘C’ based on the on-cell voltage Von. The weak block 220 may be a block that is relatively greatly affected by retention. The number of on-cells may be ‘D’ based on the on-cell voltage Von.

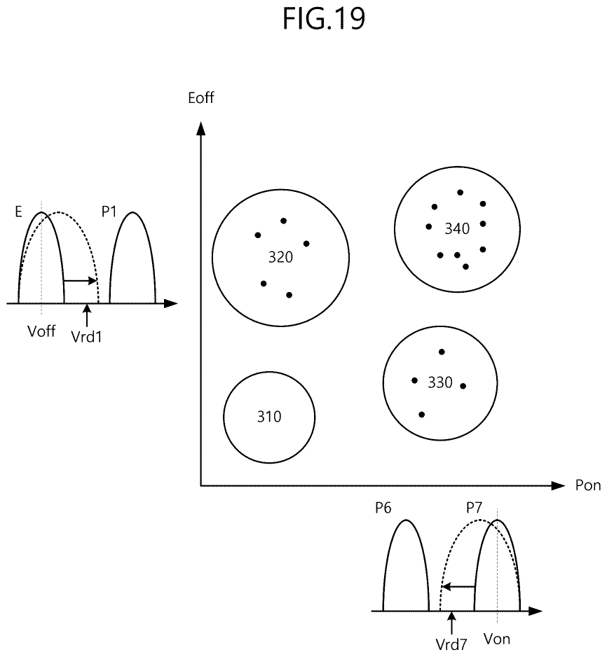

FIG. 19 is a graph illustrating the deterioration characteristics of memory cells due to read disturbance and/or retention. Referring to FIG. 19, an abscissa denotes the number of on-cells due to retention, and an ordinate denotes the number of off-cells due to read disturbance.

The first memory block group 310 is a group of memory blocks that do not have any deterioration due to retention and read disturbance. The second memory block group 320 is a group of memory blocks that do not have any deterioration due to retention and have a lot of deterioration due to read disturbance. The third memory block group 330 is a group of memory blocks that do not have any deterioration due to read disturbance and have a lot of deterioration due to retention. The fourth memory block group 340 is a group of memory blocks that have both deterioration due to read disturbance and retention.

The memory deterioration management unit 2002 may receive the number of on and/or off-cells in the erase state and the highest program state of the memory block from the memory device 1100. The memory deterioration management unit 2002 may analyze the deterioration characteristics of the memory block using the cell count. The memory deterioration management unit 2002 may change the bias conditions according to the analysis result and operate the memory device 1100 according to the changed bias conditions.

The memory deterioration management unit 2002 may analyze the deterioration characteristics of the memory block using the number of off-cells in the erase state. The memory deterioration management unit 2002 may analyze that the deterioration is due to read disturbance if the number of off-cells in the erase state is greater than a predetermined number. The memory deterioration management unit 2002 may change the program verify voltage of the first program state according to the result of analyzing the deterioration characteristics of the memory block.

The memory deterioration management unit 2002 may analyze the deterioration characteristics of the memory block using the number of on-cells in the highest program state. The memory deterioration management unit 2002 may analyze that the deterioration is due to retention if the number of on-cells in the highest program state is greater than a predetermined number. The memory deterioration management unit 2002 may reduce the ISPP program voltage application time based on the result of analyzing the deterioration characteristics of the memory block.

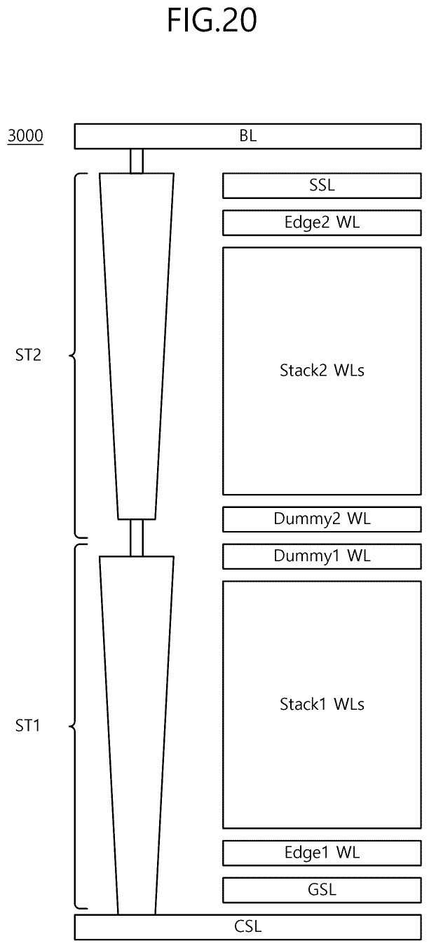

FIG. 20 is a diagram illustrating an example embodiment of a memory device having a multi-stack structure. Referring to FIG. 20, the memory device 3000 may have a first stack ST1 and a second stack ST2. The first stack ST1 may be located at the bottom, and the second stack ST2 may be located at the top.

A pillar of the memory device 3000 may be formed by bonding the first and second stacks ST1 and ST2. A plurality of dummy word lines (e.g., Dummy1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs and second edge word lines Edge2 WL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TLC or QLC.

The memory device 3000 may count the number of on-cells or off-cells in the erase state and the highest program state of the memory block. The memory device 3000 may provide cell count information to the memory controller. The memory controller may analyze the deterioration characteristics of the memory block using the cell count. The memory controller may change the bias conditions according to the analysis result and operate the memory device 3000 according to the changed bias conditions.

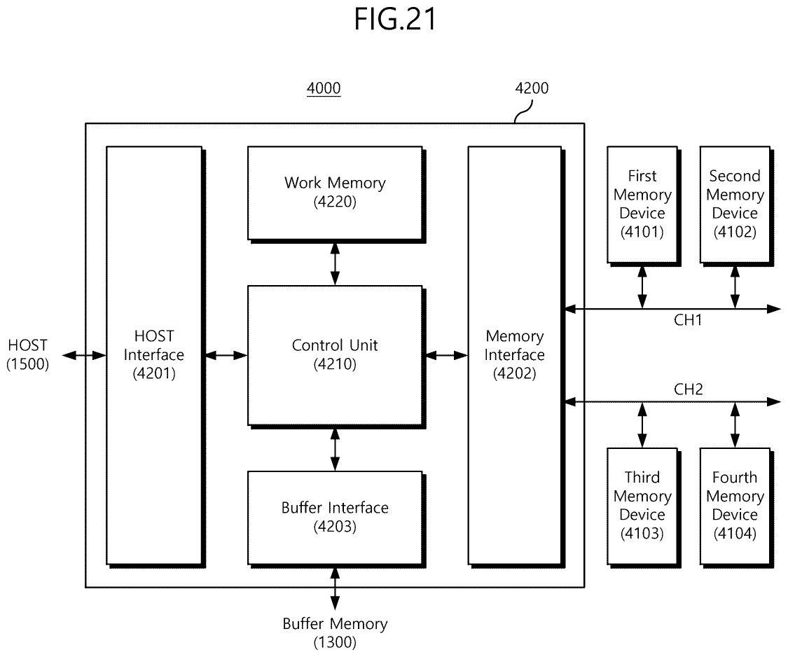

FIG. 21 is a block diagram illustrating an example in which a storage device according to an embodiment of the present disclosure is implemented with a solid state drive (SSD). Referring to FIG. 21, an SSD 4000 may include a plurality of memory devices 4101 to 4104 and an SSD controller 4200.

The first and second memory devices 4101 and 4102 may be connected with the SSD controller 4200 through a first channel CH1. The third and fourth memory devices 4103 and 4104 may be connected with the SSD controller 4200 through a second channel CH2. The number of channels connected with the SSD controller 4200 may be 2 or more. The number of memory devices connected with one channel may be 2 or more.

The SSD controller 4200 may include a host interface 4201, a memory interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding memory device or may read data from the corresponding memory device.

The SSD controller 4200 may be connected with the plurality of memory devices 4101 to 4104 through the memory interface 4202 and may be connected with a buffer memory 1300 through the buffer interface 4203. The memory interface 4202 may provide data, which are temporarily stored in the buffer memory 1300, to the plurality of memory devices through the channels CH1 and CH2. The memory interface 4202 may transfer the data read from the plurality memory devices 4101 to 4104 to the buffer memory 1300.

The control unit 4210 may analyze and process the signal received from the host 1500. The control unit 4210 may control the host 1500 or the plurality memory devices 4101 to 4104 through the host interface 4201 or the memory interface 4202. The control unit 4210 may control operations of the plurality memory devices 4101 to 4104 by using firmware for driving the SSD 4000.

The SSD controller 4200 may manage data to be stored in the plurality of memory devices 4101 to 4104. In a sudden power-off event, the SSD controller 4200 may back up the data stored in the work memory 4220 or the buffer memory 1300 to the plurality of memory devices 4101 to 4104.

A storage device according to one or more embodiments of the present disclosure may calculate the number of off-cells in an erase state and/or off-cells in the highest program state using a cell count of a memory block. The present disclosure may analyze the deterioration characteristics of a memory block using a cell count, change bias conditions according to the result of the deterioration characteristic analysis of the memory block, and operate a memory device according to the changed bias conditions. According to the present disclosure, deterioration due to read disturbance and/or retention may be reduced, and the performance and reliability of a memory device may be improved.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A storage device comprising:
a memory device comprising a plurality of memory blocks; and
a memory controller configured to manage, based on one or more deterioration characteristics, the plurality of memory blocks,
wherein the memory controller is further configured to:
receive, from the memory device, at least one of a number of off-cells of memory cells of the memory device in an erase state or a highest program state or a number of on-cells of the memory cells of the memory device in the erase state or the highest program state,
analyze the one or more deterioration characteristics of the plurality of memory blocks based on the least one of the number of off-cells or the number of on-cells to obtain an analysis result,
change one or more bias conditions based on the analysis result, and
operate the memory device based on the changed one or more bias conditions.

2. The storage device of claim 1, wherein the memory controller is further configured to analyze the one or more deterioration characteristics of the plurality of memory blocks based on the number of off-cells in the erase state.

3. The storage device of claim 2, wherein the memory controller determines that deterioration of the plurality of memory blocks is due to a read disturbance based on the number of off-cells in the erase state being greater than a predetermined number.

4. The storage device of claim 2, wherein the memory controller is further configured to change a program verify voltage of a first program state based on the analysis result.

5. The storage device of claim 2, wherein the memory controller is further configured to analyze the one or more deterioration characteristics of the plurality of memory blocks based on the number of on-cells in the highest program state.

6. The storage device of claim 5, wherein the memory controller determines that deterioration of the plurality of memory blocks is due to retention of the plurality of memory blocks based on the number of on-cells in the highest program state being greater than a predetermined number.

7. The storage device of claim 6, wherein the memory controller is further configured to reduce an incremental step pulse programming (ISPP) program voltage application time based on the analysis result.

8. The storage device of claim 1, wherein the memory controller is further configured to:
count, using a cell counter in the memory device, the at least one of the number of off-cells in the erase state or the highest program state or the number of on-cells in the erase state and the highest program state, and analyze the one or more deterioration characteristics of the plurality of memory blocks based on the at least one of the number of off-cells in the erase state or the highest program state or the number of on-cells of memory cells in the erase state and the highest program state;
change the one or more bias conditions of the memory device based on the analysis result; and
control the memory device to operate based on the changed one or more bias conditions.

9. The storage device of claim 8, wherein the memory controller is further configured to analyze the one or more deterioration characteristics of the plurality of memory blocks based on the number of off-cells in the erase state and the number of on-cells in the highest program state.

10. The storage device of claim 9, wherein the memory controller is further configured to increase a program verify voltage of a first program state based on the number of off-cells in the erase state being greater than a predetermined number, and decrease an incremental step pulse programming (ISPP) program voltage application time based on the number of on-cells in the highest program state being greater than a predetermined number.

11. A memory controller which controls a memory device, the memory controller comprising:
a processor configured to:
count, using a cell counter of the memory device, at least one a number of on-cells of memory cells of the memory device in an erase state or a highest program state or a number of off-cells of the memory cells in the erase state or the highest program state;
analyze one or more deterioration characteristics of a memory block the at least one of the number of on-cells or the number of off-cells to obtain an analysis result;
change one or more bias conditions of the memory device based on the analysis result; and
control the memory device to operate based on the changed one or more bias conditions.

12. The memory controller of claim 11, wherein the processor is further configured to receive deterioration management data from the memory device when the memory device is powered up, and analyze the one or more deterioration characteristics of the memory block based on the deterioration management data.

13. The memory controller of claim 11, wherein the processor is further configured to analyze the one or more deterioration characteristics of the memory block based on the number of off-cells in the erase state and the number of on-cells in the highest program state.

14. The memory controller of claim 13, wherein the processor is further configured to increase a program verify voltage of a first program state based on the number of off-cells in the erase state being greater than a predetermined number.

15. The memory controller of claim 13, wherein the processor is further configured to reduce an incremental step pulse programming (ISPP) program voltage application time based on the number of on-cells in the highest program state being greater than a predetermined number.

16. A management method of a memory controller controlling a memory device, the management method comprising:
counting at least one of a number of on-cells of memory cells of the memory device in an erase state or a highest program state or a number of off-cells of the memory cells of the memory device in the erase state or the highest program state;
analyzing one or more deterioration characteristics of a memory block based on the at least one of the number of on-cells or the number of off-cells to obtain an analysis result;
changing one or more bias conditions of the memory device according to the analysis result; and
operating the memory device according to the changed one or more bias conditions.

17. The management method of claim 16, further comprising:
receiving deterioration management data from the memory device when the memory device is powered up.

18. The management method of claim 16, wherein the analyzing the one or more deterioration characteristics includes analyzing the one or more deterioration characteristics of the memory block based on the number of off-cells in the erase state and the number of on-cells in the highest program state.

19. The method of claim 18, wherein the changing the one or more bias conditions includes increasing a program verify voltage of a first program state based on the number of off-cells in the erase state being greater than a predetermined number.

20. The method of claim 19, wherein the changing the one or more bias conditions includes reducing an incremental step pulse programming (ISPP) program voltage application time based on the number of on-cells in the highest program state being greater than a predetermined number.
